(19) United States
(12) Patent Application Publication
(10) Pub. No.: US 2010/0238338 A1
(43) Pub. Date: Sep. 23, 2010

(54) SOLID STATE IMAGING DEVICE, IMAGING APPARATUS AND METHOD OF DRIVING SOLID STATE IMAGING DEVICE

(75) Inventor: Makoto SHIZUKUISHI, Kanagawa (JP)

Correspondence Address: Studebaker & Brackett PC, One Fountain Square, 11911 Freedom Drive, Suite 750, Reston, VA, 20190, US

(73) Assignee: FUJIFILM CORPORATION, Tokyo (JP)

(21) Appl. No.: 12/729,512

(22) Filed: Mar. 23, 2010

(30) Foreign Application Priority Data
Mar. 23, 2009 (JP) 2009-070775

(51) Int. Cl. H04N 5/335; H01L 31/14

(52) U.S. Cl. 348/308; 257/290; 257/E31.097; 257/315; 348/E05.091

(57) ABSTRACT

A solid state imaging device includes: a photoelectric converting portion that is formed in a semiconductor substrate and serves to generate an electric charge depending on an incident light; a floating gate that stores the electric charge generated in the photoelectric converting portion; and a transistor that have a control gate and provided with the floating gate between the control gate and the semiconductor substrate. A specific resistance of the floating gate and that of the photoelectric converting portion are almost equal to each other.

### CROSS-REFERENCE TO RELATED APPLICATIONS

This application is based on and claims priority under 35 USC 119 from Japanese Patent Application No. 2009-070775 filed on Mar. 23, 2009; the entire contents of which are incorporated herein by reference.

### BACKGROUND

1. Technical Field

The present invention relates to a solid state imaging device, an imaging apparatus and a method of driving a solid state imaging device.

2. Related Art

At present, there has been proposed a solid state imaging device having a structure in which an electric charge generated by a photodiode is recorded by a nonvolatile MOS memory transistor having an electric charge storing portion such as a floating gate and a signal corresponding to the electric charge is read. With the structure, a threshold voltage of the memory transistor is changed corresponding to an amount of the electric charges to be injected from the photodiode into the floating gate and the change in the threshold voltage is read as an imaging signal.

The Patent Document 1 (JP-A-2002-280537 corresponding to US-A-2002/0171102) discloses a solid state imaging apparatus in which each pixel formed on a semiconductor substrate includes a photodiode and a nonvolatile memory structure for fetching an electric charge generated by the photodiode and generating a signal voltage corresponding to the electric charge.

In a solid state imaging device including a memory transistor, electric charges stored in a floating gate are required to be once erased before carrying out a next imaging operation. There is room for an improvement in that a part of the electric charges remain in the floating gate and a variation is caused in a threshold voltage, resulting in a variation in a sensitivity of the imaging device if the electric charges stored in the floating gate cannot be erased completely.

Moreover, there is a possibility that the electric charges remaining in the floating gate might be superposed on a next imaging signal and an afterimage or a noise might be thus made.

For this reason, a state (a so-called depleting state) in which (i) the electric charges do not remain in the floating gate at all or (ii) few electric charges remain is required to be brought every imaging operation. There has originally not been a technical concept in which the floating gate is brought into the depleting state.

### SUMMARY

An illustrative aspect of the invention is to provide a solid state imaging device, an imaging apparatus and a method of driving a solid state imaging device which can suppress a variation in a sensitivity or a generation of an afterimage and can enhance picture quality.

According to a first aspect of the invention, a solid state imaging device includes: a photoelectric converting portion that is formed in a semiconductor substrate and serves to generate an electric charge depending on an incident light; a floating gate that stores the electric charge generated in the photoelectric converting portion; and a transistor that have a control gate and provided with the floating gate between the control gate and the semiconductor substrate. A specific resistance of the floating gate and that of the photoelectric converting portion are almost equal to each other.

According to a second aspect of the invention, a method of driving a solid state imaging device including a photoelectric converting portion formed in a semiconductor substrate and serving to generate an electric charge depending on an incident light; a floating gate for storing the electric charge generated in the photoelectric converting portion; and a transistor having a control gate and provided with the floating gate between the control gate and the semiconductor substrate, a specific resistance of the floating gate and that of the photoelectric converting portion being almost equal to each other, the method includes: applying an erasing pulse to the control gate to discharge the electric charge stored in the floating gate.

According to the solid state imaging device described in the first and second aspect of the invention, the solid state imaging device may be included in an imaging apparatus.

According to the configurations described above, a threshold voltage of a memory transistor is changed depending on an amount of the electric charges generated by the photoelectric converting portion and the change in the threshold voltage is read as an imaging signal. After the imaging signal is read, there is carried out a reset driving operation for extracting the electric charges stored in the floating gate toward the semiconductor substrate or the photoelectric converting portion side and thus erasing them. At this time, a specific resistance of the floating gate is set to be almost equal to that of the photoelectric converting portion. Therefore, it is possible to smoothly move the electric charges stored in the floating gate toward the photoelectric converting portion side. In the reset driving operation, thus, it is possible to partially or wholly bring the floating gate into a depleting state. By preventing the electric charges from remaining in the floating gate, it is possible to suppress a variation in a sensitivity of the solid state imaging device which is caused by a variation in a threshold voltage. Moreover, it is possible to prevent the electric charges from remaining in the floating gate. Thus, it is possible to suppress a situation in which the remaining electric charges are superposed on a next imaging signal, resulting in a generation of an afterimage or a noise.

Also, with the configurations described above, it is possible to provide a solid state imaging device, an imaging apparatus and a method of driving a solid state imaging device which can enhance picture quality by suppressing a variation in a sensitivity and preventing an afterimage or a noise from being generated.

### BRIEF DESCRIPTION OF THE DRAWINGS

FIG. 1 is a plan view showing a schematic structure of a solid state imaging device for explaining an embodiment according to the invention.

FIG. 2 is a sectional view showing the solid state imaging device illustrated in FIG. 1.

FIG. 3 is an equivalent circuit diagram showing the solid state imaging device illustrated in FIG. 1.

FIG. 4 is a circuit diagram showing another example of the structure of the solid state imaging device.

FIGS. 5A and 5B are diagrams for explaining a gradient of an electric potential and a movement of an electric charge. And,

FIG. 6 is a timing chart for explaining a method of driving the solid state imaging device.

### DETAILED DESCRIPTION

A solid state imaging device for explaining an exemplary embodiment according to the invention will be described below with reference to the drawings. The solid state imaging device is mounted on an imaging apparatus such as a digital camera or a digital video camera so as to be used.

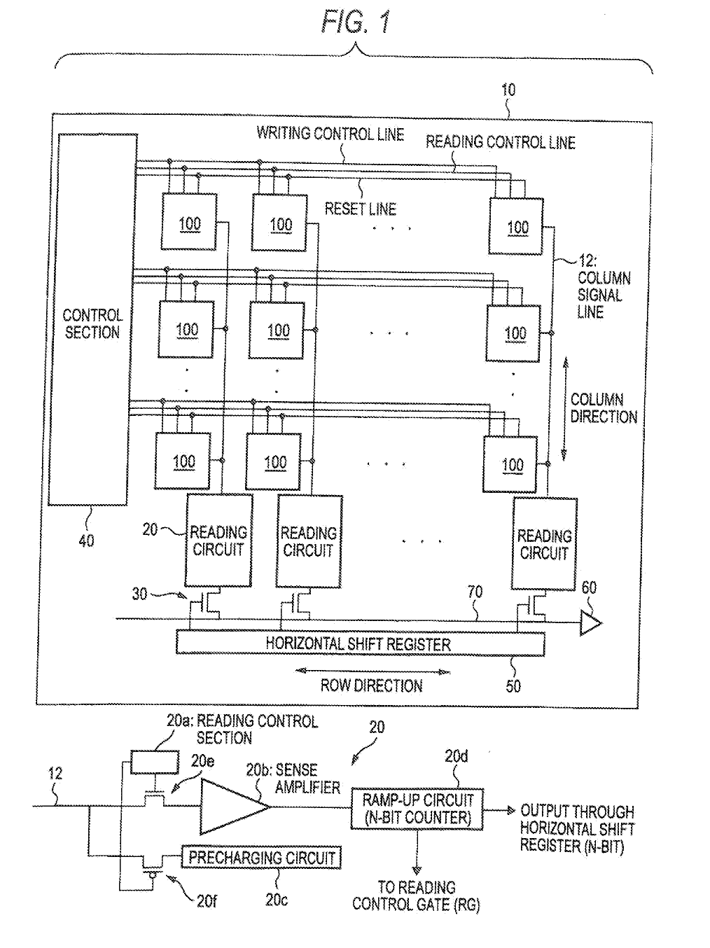

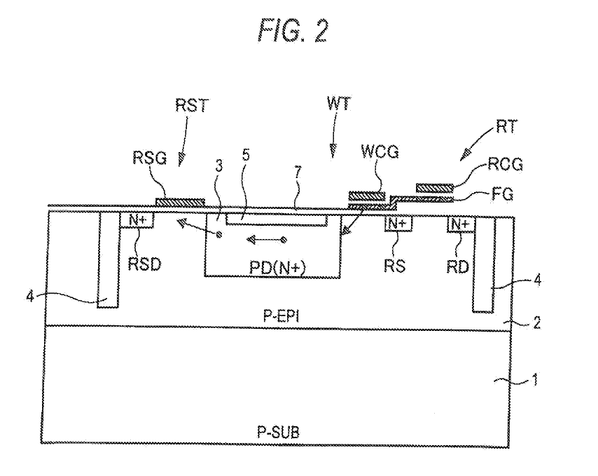

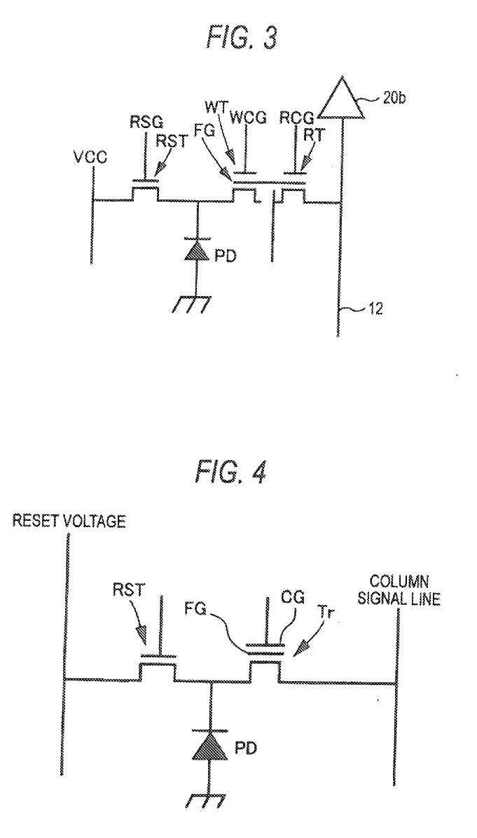

FIG. 1 is a typical plan view showing a schematic structure of the solid state imaging device for explaining the embodiment according to the invention. FIG. 2 is a sectional view typically showing a pixel portion illustrated in FIG. 1. FIG. 3 is an equivalent circuit diagram showing the pixel portion illustrated in FIG. 2.

A solid state imaging device 10 includes a plurality of pixel portions 100 which is arranged like an array (a square grid) in a row direction and a column direction which is orthogonal thereto over the same plane.

The pixel portion 100 includes an N-type impurity layer 3 formed in a semiconductor substrate constituted by a P-type silicon substrate 1 and a P-type epitaxial layer formed thereon (which will be hereinafter referred to as a P well layer). The N-type impurity layer 3 is formed in a P well layer 2, and a photodiode (PD) functioning as a photoelectric converting portion is formed by PN junction of the N-type impurity layer 3 and the P well layer 2. The N-type impurity layer 3 will be hereinafter referred to as a photoelectric converting portion 3. The photoelectric converting portion 3 is a so-called embedded photodiode having a P-type impurity layer 5 formed on a surface thereof in order to bring a complete depletion or to suppress a dark current.

An oxide layer 7 such as silicon oxide is formed on an upper surface of the semiconductor substrate.

A transistor is formed in the semiconductor substrate. The transistor generates a voltage signal (hereinafter referred to as an imaging signal) corresponding to an electric charge produced in the photoelectric converting portion 3.

In the example of the structure, the transistor includes a writing transistor WT and a reading transistor RT. The writing transistor WT and the reading transistor RT are provided side by side adjacently to the photoelectric converting portion 3. Moreover, components of the pixel portions 100 in the P well layer 2 are isolated from each other through a device isolating layer 4.

It is possible to apply, to a device isolating method, the LOCOS (Local Oxidation of Silicon) process, the STI (Shallow Trench Isolation) process and a high concentration impurity ion implanting process.

The writing transistor WT includes the photoelectric converting portion 3 functioning as a source region and a drain region and a floating gate FG formed on the oxide layer 7. Moreover, the writing transistor WT includes a writing control gate WCG provided on the floating gate FG through an insulating layer. The writing transistor WT is an MOS transistor having a two-terminal structure in which a source (serving as a drain) is connected to the photoelectric converting portion 3 as shown in FIG. 3.

For a conductive material constituting the writing control gate WCG, it is possible to use polysilicon, for example. It is also possible to use doped polysilicon which is doped with phosphorus (P), arsenic (As) or boron (B) in a high concentration. Alternatively, it is also possible to use silicide or self-align silicide in which various metals such as titanium (Ti) or tungsten (W) and silicon are combined.

The reading transistor RT has an MOS transistor structure including a reading drain RD to be a drain region which is provided adjacently to the device isolating layer 4 and is formed by an N-type impurity in a high concentration, a reading source RS to be a source region which is provided slightly apart from the reading drain RD and is formed by an N-type impurity, a reading control gate RCG to be a gate electrode which is provided through the oxide layer 7 above the semiconductor substrate between the reading drain RD and the reading source RS, and the floating gate FG provided between the reading control gate RCG and an oxide layer.

For a conductive material constituting the reading control gate RCG, it is possible to use the same material as that of the writing control gate WCG. A column signal line 12 is connected to the reading drain RD. A ground line is connected to the reading source RS. The reading drain RD has an impurity concentration regulated to take an ohmic contact with the column signal line 12. The reading source RS has an impurity concentration regulated to take the ohmic contact with the ground line.

The floating gate FG is an electrode which is provided through the oxide layer 7 above the semiconductor substrate and electrically floats. The writing control gate WCG and the reading control gate RCG are provided on the floating gate FG through an insulating layer such as silicon oxide. For a conductive material constituting the floating gate FG, it is possible to use the same material as that of the writing control gate WCG or the reading control gate RCG.

There is employed a structure in which a thickness of the oxide layer 7 provided above the semiconductor substrate on the writing transistor WT side is smaller than that of the oxide layer 7 provided above the semiconductor substrate on the reading transistor RT side. The structure is effective in that an electric charge can easily be injected from the photoelectric converting portion 3 into the floating gate FG on the writing transistor WT side and the electric charge stored in the reading transistor RT is discharged to the substrate with difficulty in a reading operation (a read disturb is hard to occur).

It was understood, in a common sense, that a transistor to be an active device for carrying out pixel selection, resetting, signal recording and reading in a general solid state imaging device does not function with two terminals, and nobody made an attempt.

The solid state imaging device according to the embodiment has the structure in which the writing transistor WT and the reading transistor RT share the floating gate FG For this reason, the writing transistor WT is chiefly required to carry out a single operation of writing (an electric charge is injected and recorded onto the floating gate FG) and an electric charge transfer in only one direction, and a signal can also be read on the adjacent reading transistor RT side by the shared FG structure. Therefore, there is no problem of an operation even if the writing transistor WT has the two-terminal structure.

In the solid state imaging device 10 according to the embodiment, therefore, the writing transistor WT is set to have the two-terminal structure, resulting in a simplification of the structure.

By applying a writing control voltage of 7V to 15V to the control gate WCG, for example, the writing transistor WT can inject and record an electric charge generated in the photographic converting portion 3 onto the floating gate FG.

The reading transistor RT is an MOS transistor having a three-terminal structure including the floating gate FG, the source region RS, the drain region RD and the control gate RCG. By applying, to the control gate RCG, a reading control voltage to be increased continuously or stepwise in a state in which a drain voltage of 0.7V is applied to the drain region RD, for example, and detecting a voltage value (a threshold voltage) of the control gate RCG when a channel region of the reading transistor RT is conducted, the reading transistor RT can read, onto an outside, the detected value of the control gate RCG as an imaging signal corresponding to the electric charge stored in the floating gate FG.

It is also possible to employ a structure in which the floating gate FG is provided separately in the writing transistor WT and the reading transistor RT respectively and the two separated floating gates FG are electrically connected to each other through a wiring in addition to a single structure in which the floating gate FG is shared by the writing transistor WT and the reading transistor RT. Moreover, the writing control gate WCG and the photoelectric converting portion 3 may be caused to partially overlap with each other in such a manner that the electric charge can easily be injected from the photoelectric converting portion 3 into the floating gate FG.

The writing transistor WT may be constituted by three terminals including a floating gate, a source region, a drain region and a control gate in the same manner as the reading transistor RT.

The pixel portion 100 has a structure in which a light is not incident on a region other than a part of the photoelectric converting portion 3 through a shielding layer which is not shown.

The solid state imaging device 10 includes a control section 40 for controlling the writing transistor WT and the reading transistor RT, a reading circuit 20 for detecting the threshold voltage of the reading transistor RT, a horizontal shift register 50 for carrying out a control to sequentially read a threshold voltage corresponding to one line which is detected by the reading circuit 20 as an imaging signal onto a signal line 70, and an output amplifier 60 connected to the signal line 70.

The reading circuit 20 is provided corresponding to each column constituted by a plurality of pixel portions 100 which is arranged in a column direction, and is connected to the reading drain RD of each of the pixel portions 100 in a corresponding column through the column signal line 12. Moreover, the reading circuit 20 is also connected to the control section 40.

As shown in FIG. 1B, the reading circuit 20 has a structure including a reading control section 20a, a sense amplifier 20b, a precharging circuit 20c, a ramp-up circuit 20d, and transistors 20e and 20f.

When reading a signal from the pixel portion 100, the reading control section 20a turns ON the transistor 20f to supply a drain voltage through the column signal line 12 from the precharging circuit 20c to the reading drain RD of the pixel portion 100 (precharging). Next, the reading control section 20a turns ON the transistor 20e to conduct the reading drain RD of the pixel portion 100 to the sense amplifier 20b.

The sense amplifier 20b monitors a voltage of the reading drain RD of the pixel portion 100 and detects that the voltage is changed, and gives a purport to the ramp-up circuit 20d. For example, the sense amplifier 20b detects that the drain voltage precharged by the precharging circuit 20c is dropped and inverts an output thereof.

The ramp-up circuit 20d includes an N-bit (for example, N=8 to 12) counter and supplies a ramp waveform voltage to be gradually increased or decreased to the reading control gate RCG of the pixel portion 100 through the control section 40, and furthermore, outputs a count value (a combination of N numerals of one and zero) corresponding to a value of the ramp waveform voltage.

When the voltage of the reading control gate RCG exceeds the threshold voltage of the reading transistor RT, the reading transistor RT is conducted and an electric potential of the column signal line 12 which is precharged is dropped at this time. This is detected by the sense amplifier 20b so that an inverted signal is output. The ramp-up circuit 20d holds (latches) a count value corresponding to a value of a ramp waveform voltage at a time that the inverted signal is received. Consequently, it is possible to read a change in the threshold voltage (an imaging signal) as a digital value (a combination of one and zero).

When a single horizontal selecting transistor 30 is selected by the horizontal shift register 50, a count value held by the ramp-up circuit 20d connected to the horizontal selecting transistor 30 is output to the signal line 70 and is output as an imaging signal from the output amplifier 60.

The method of reading the change in the threshold voltage of the reading transistor RT through the reading circuit 20 is not restricted to the foregoing. For example, it is also possible to read a drain current of the reading transistor RT as an imaging signal in the case in which a certain voltage is applied to the reading control gate RCG and the reading drain RD.

The semiconductor substrate of the pixel portion 100 is provided with a reset transistor RST for reading the imaging signal and then discharging the electric charge stored in the photoelectric converting portion 3. The reset transistor RST includes the photoelectric converting portion 3 for functioning as a source region and a reset drain RSD to be a drain region which is provided adjacently to the device isolating layer 4 and is formed by an N-type impurity having a high concentration, and a reset control gate RSG is provided through the oxide layer 7 on the semiconductor substrate between the photoelectric converting portion 3 and the reset drain RSD. The reset control gate RSG can be constituted by the same conductive material as the writing control gate WCG or the reading control gate RCG. A drain voltage VCC is previously applied to the reset drain RSD.

The control section 40 is connected through a writing control line, a reading control line and a reset line to the writing control gate WCG, the reading control gate RCG and the reset transistor RST of each of the pixel portions 100 arranged in the row direction on each of lines which includes the pixel portions 100, respectively.

The control section 40 controls the writing transistor WT to carry out a driving operation for injecting and storing the electric charge generated in the photoelectric converting portion 3 into the floating gate FG. Examples of a method of injecting the electric charge into the floating gate FG include an FN tunnel injection for injecting an electric charge by using a Fowler-Nordheim (F-N) tunnel current, a direct tunnel injection and a hot electron injection.

Moreover, the control section 40 controls the reading transistor RT by the method, thereby carrying out a driving operation for reading an imaging signal corresponding to the electric charge stored in the floating gate FG.

Furthermore, the control section 40 controls the reset transistor RST, thereby carrying out a reset driving operation for extracting and erasing the electric charge stored in the photoelectric converting portion 3. More specifically, the reset control gate RSG of the reset transistor RST is connected to the control section 40 through the reset line. When a reset pulse is input from the control section 40, the reset transistor RST is brought into an ON state so that the electric charge of the photoelectric converting portion 3 is moved to the reset drain RSD and is thus discharged. Consequently, a period for which the electric charge of the photoelectric converting portion 3 is discharged is set to be a reset period.

In the solid state imaging device, moreover, a driving operation for erasing the electric charge stored in the floating gate FG is carried out for the reset period of the electric charge in the photoelectric converting portion 3. The driving operation for erasing the electric charge stored in the floating gate FG will be described below.

A voltage is applied to the reading drain RD by controlling the reading control section 20a and the precharging circuit 20c. The precharging circuit 20c can generate voltages having two types of levels, that is, a voltage (Vr) to be applied to the reading drain RD in order to read an imaging signal and a voltage (Vcc) to be applied to the reading drain RD in order to erase an electric charge and can supply them to the column signal line 12, and supplies the voltage Vcc to the reading drain RD in accordance with an instruction given from the control section 40 in the erasure of the electric charge. The reading control section 20a turns OFF the transistor 20e and turns ON the transistor 20f in accordance with the instruction given from the control section 40.

Although the control section 40 is provided in the solid state imaging device 10 in FIG. 1, the imaging apparatus side provided with the solid state imaging device 10 is caused to have the function of the control section 40.

Although the structure for reading the electric charge of the photoelectric converting portion 3 in the solid state imaging device 10 includes two transistors having the writing transistor WT and the reading transistor RT, a single transistor may be provided as shown in an equivalent circuit diagram of FIG. 4. With the structure, there are provided a photodiode PD functioning as the photoelectric converting portion, a transistor Tr for generating a threshold voltage corresponding to an electric charge of the photodiode PD, and the reset transistor RST for erasing the electric charge generated by the photodiode PD. The transistor Tr includes the photodiode PD functioning as a source, a drain connected to the column signal line, a control gate CG, and the floating gate FG. The reset transistor RST includes the photodiode PD functioning as a source, a drain to which a reset voltage is applied, and a reset control gate. In a reset driving operation, a reset pulse is applied to the reset control gate in a state in which the reset voltage is applied to the drain, and the reset transistor RST is brought into an ON state. Thus, the electric charge stored in the photodiode PD is extracted and discharged after imaging.

The solid state imaging device 10 is constituted in such a manner that a specific resistance of the floating gate FG is almost equal to that of the photoelectric converting portion 3. The specific resistance corresponds to a physical property value indicative of a difficulty of a conduction of electricity in a material constituting the member and is also referred to as an electric resistivity or a resistivity. Moreover, the specific resistance is equivalent to an inverse number of an electric conductivity. By employing a structure in which the specific resistances of the floating gate FG and the photoelectric converting portion 3 are almost equal to each other, it is possible to easily set the floating gate FG and the photoelectric converting portion 3 to have an equal electric potential and to also bring the floating gate FG into a depleting state in addition to the photoelectric converting portion 3 for a reset period.

In the floating gate FG, a peak value of an impurity concentration is 1×10¹⁸ to 1×10¹⁹/cm³. In the photoelectric converting portion 3, a peak value of an impurity concentration is equal to or smaller than 1×10¹⁸/cm³. In other words, “the specific resistances are almost equal to each other” can also imply that a difference between the peak values of the impurity concentrations of the floating gate FG and the photoelectric converting portion 3 has one digit or less.

In the case in which the transistor has a structure of an N-channel device, the floating gate FG is obtained by implanting P (phosphorus) or As (arsenic) as an impurity (a dopant) into polysilicon within the concentration range, for example. In the case in which the transistor has a structure of a P-channel device, the floating gate FG is obtained by implanting B (boron) as the impurity (the dopant) into the polysilicon within the concentration range, for example.

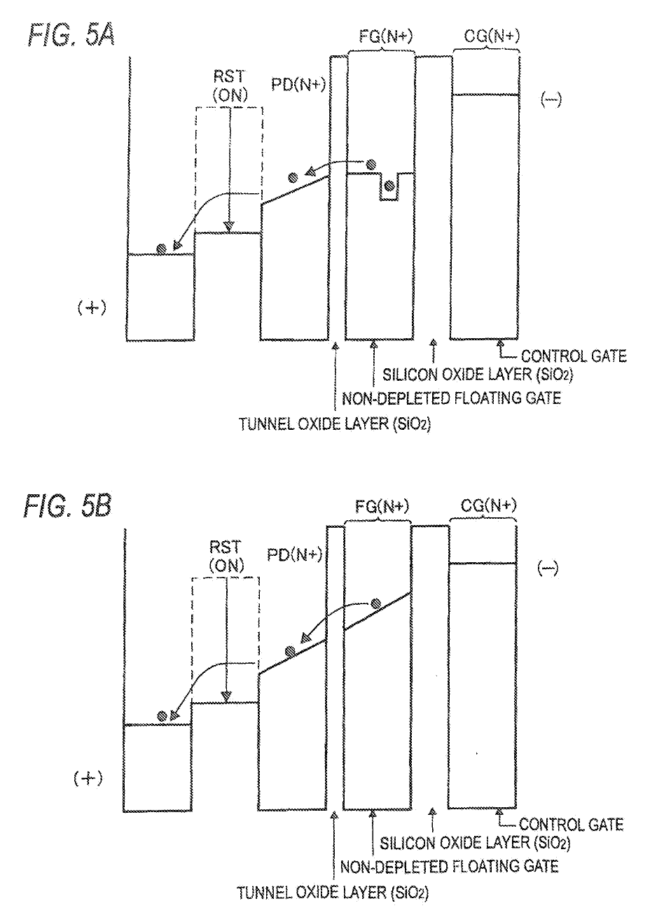

FIG. 5A shows a potential in the case in which the floating gate FG is not set into the depleting state, and FIG. 5B shows a potential in the case in which the floating gate FG is set into the depleting state. FIG. 5A shows the case in which the specific resistances of the floating gate FG and the photodiode PD are not set to be almost equal to each other. At this time, when the reset transistor RST is set into an ON state for the reset period, a potential gradient is constituted in the photodiode PD so that the stored electric charge can be discharged to a reset drain side. However, the potential gradient is not constituted in the floating gate FG. Therefore, the stored electric charge is apt to remain.

On the other hand, FIG. 5B shows the case in which the specific resistances of the floating gate FG and the photodiode PD are set to be almost equal to each other. At this time, when the reset transistor RST is set into the ON state for the reset period, an electric field is applied to the photodiode PD and the floating gate FG so that an electric gradient is constituted for both of them. Consequently, the electric charge stored in the photodiode PD and the floating gate FG can be smoothly moved to the reset drain side. For this reason, the electric charge remains in the floating gate FG with difficulty.

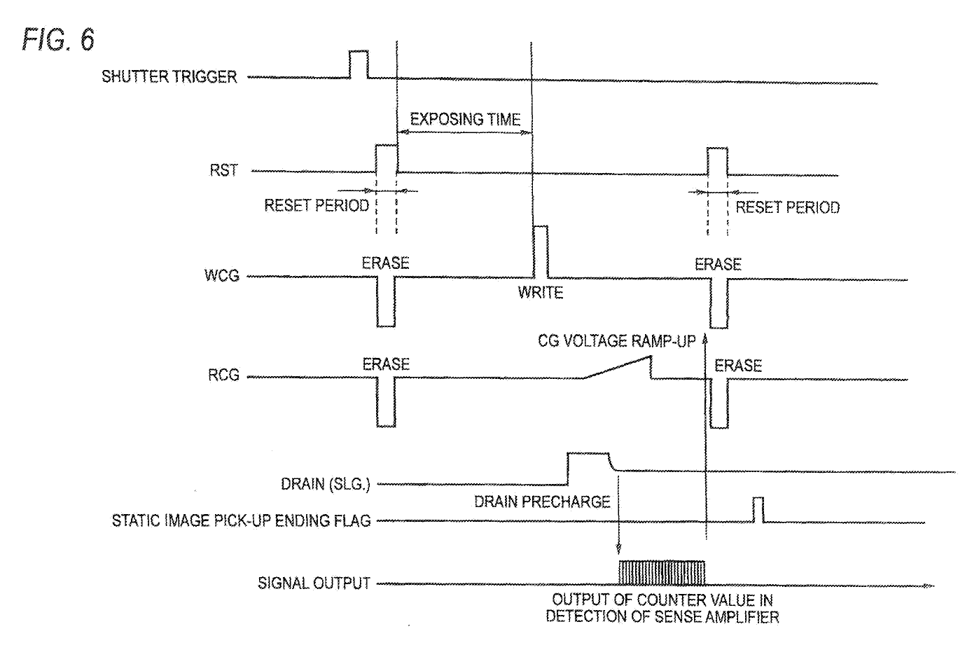

Next, a method of driving the solid state imaging device will be described with reference to FIG. 6. Description will be given by taking, as an example, a driving operation in static image pickup through an imaging apparatus such as a digital camera using the solid state imaging device shown in FIG. 1.

First of all, when an instruction for imaging is input by a user, a shutter trigger is generated. The control section 40 sets the reset transistor RST into the ON state, and at the same time, a pulse signal is applied to the control gate WCG of the writing transistor WT and the control gate RCG of the reading transistor RT to carry out a reset driving operation for discharging all of the electric charges stored in the photoelectric converting portion 3 to the reset drain of the reset transistor RST before starting the imaging operation. The reset driving operation brings a state in which the electric charge is not present in the photoelectric converting portion 3 in each of the pixel portions 100. At the same time, in the case in which the electric charge stored in the floating gate FG is present, it is also discharged to the reset drain via the photoelectric converting portion 3.

An exposure is executed until a writing pulse is input to the control gate WCG of the writing transistor WT after the reset driving operation, and the electric charge is generated in the photoelectric converting portions 3 in all of the pixel portions 100 for the exposing period.

At the end of the exposing period, a writing pulse is input to the control gate WCG of the writing transistor WT, and the electric charges generated in the photoelectric converting portions 3 in all of the pixel portions 100 for the exposing period are injected into the floating gate FG via the oxide layer 7 (the FN tunneling or direct tunneling injection). For the exposing period, the electric charges are stored in all of the pixel portions 100 at the same time. The thickness of the oxide layer 7 is set to be 1 to 5 nm, for example, in such a manner that the electric charge generated in the photoelectric converting portion 3 is injected into the floating gate FG quickly and reliably.

After a storing period for injecting the electric charge from the photoelectric converting portion 3 to the floating gate FG is ended, an operation for reading an imaging signal is executed. For an imaging signal reading period, the reading drain RD of the reading transistor RT is set to have a predetermined potential and a ramp waveform voltage is applied to the reading control gate RCG of the reading transistor RT in each of the pixel portions 100 for each line. Then, a count value corresponding to a value of the ramp waveform voltage in a drop of the potential of the reading drain RD is held in each reading circuit 20 and is output as an imaging signal from the output amplifier 60.

The control section 40 executes a driving operation for reading the imaging signal with a timing shifted every line. After the imaging signals are sequentially read from all of the pixel portions 100, the control section 40 brings the reset transistor RST into the ON state, thereby starting a reset period for erasing the electric charge stored in the photoelectric converting portion 3. An erasing pulse is applied to the writing control gate WCG and the reading control gate RCG for the reset period and the electric charge stored in the floating gate FG is extracted toward the photoelectric converting portion 3 side. Then, a static image pick-up ending flag is set to end the static image pick-up.

According to the structure of the solid state imaging device 10, the specific resistances of the floating gate FG and the photoelectric converting portion 3 are set to be almost equal to each other. Therefore, it is possible to smoothly move the electric charge stored in the floating gate FG to the photoelectric converting portion 3 side. In the reset driving operation, thus, the floating gate FG can be brought into the depleting state partially or wholly. By preventing the electric charge from remaining in the floating gate FG, it is possible to suppress a variation in the sensitivity of the solid state imaging device 10 which is caused by a variation in the threshold voltage. By preventing the electric charge from remaining in the floating gate FG, moreover, it is possible to suppress a generation of an afterimage or a noise due to a superposition of the remaining electric charge on a next imaging signal.

The electric charge of the floating gate FG may be discharged from the semiconductor substrate, the source or the drain. By discharging the electric charge of the floating gate FG for the reset period for which the electric charge stored in the photoelectric converting portion 3 is erased, it is possible to erase the electric charge and to reset the photoelectric converting portion 3 at the same time. Therefore, it is possible to increase a speed of an imaging sequence, which is more preferable.

Moreover, the impurity concentration of the floating gate FG can be decreased to be almost equal to that of the photodiode functioning as the photoelectric converting portion 3. Therefore, the electric charge injected into the floating gate FG can be prevented from leaking toward the semiconductor substrate side such as silicon. Thus, it is also possible to produce an advantage that a data retention (holding) characteristic can be improved.

Although it is assumed that an electric charge to be handled (an electric charge to be fetched as an imaging signal) is an electron in the above description, a thinking manner is the same also in the case in which the electric charge to be handled is a hole. In the case in which the electric charge to be handled is the hole, it is preferable to replace N and P regions with each other in the drawings and to reverse a polarity of a voltage to be applied to each portion.

And the exemplary embodiment discloses the following configurations. Specifically,

[1] there is disclosed a solid state imaging device including: a photoelectric converting portion that is formed in a semiconductor substrate and serves to generate an electric charge depending on an incident light; a floating gate that stores the electric charge generated in the photoelectric converting portion; and a transistor that have a control gate and provided with the floating gate between the control gate and the semiconductor substrate. A specific resistance of the floating gate and that of the photoelectric converting portion are almost equal to each other.

[2] According to the solid state imaging device of [1], the floating gate may have a peak value of an impurity concentration which is 1×10¹⁸ to 1×10¹⁹/cm³.

[3] According to the solid state imaging device of [1] or [2], the photoelectric converting portion may have a peak value of an impurity concentration which is equal to or smaller than 1×10¹⁸/cm³.

[4] According to the solid state imaging device of any one of [1] to [3], an impurity contained in the floating gate may be phosphorus or arsenic.

[5] The solid state imaging device of any one of [1] to [3], an impurity contained in the floating gate may be boron.

[6] There is disclosed a method of driving a solid state imaging device including a photoelectric converting portion formed in a semiconductor substrate and serving to generate an electric charge depending on an incident light; a floating gate for storing the electric charge generated in the photoelectric converting portion; and a transistor having a control gate and provided with the floating gate between the control gate and the semiconductor substrate, a specific resistance of the floating gate and that of the photoelectric converting portion being almost equal to each other, the method including: applying an erasing pulse to the control gate to discharge the electric charge stored in the floating gate.

[7] According to the method of driving the solid state imaging device of [6], the electric charge stored in the floating gate may be discharged for a reset period for which the electric charge stored in the photoelectric converting portion is reset.

[8] According to the method of driving the solid state imaging device of [6] or [7], the floating gate may have a peak value of an impurity concentration which is 1×10¹⁸ to 1×10¹⁹/cm³.

[9] According to the method of driving a solid state imaging device of any one of [6] to [8], the photoelectric converting portion may have a peak value of an impurity concentration which is equal to or smaller than 1×10¹⁸/cm³.

[10] According to the method of driving a solid state imaging device of any one of [6] to [9], an impurity contained in the floating gate may be phosphorus or arsenic.

[11] According to the method of driving a solid state imaging device of any one of [6] to [9], an impurity contained in the floating gate may be boron.

[12] There is disclosed an imaging apparatus including the solid state imaging device of any one of [1] to [5].

What is claimed is:

1. A solid state imaging device comprising:
a photoelectric converting portion that is formed in a semiconductor substrate and serves to generate an electric charge depending on an incident light;
a floating gate that stores the electric charge generated in the photoelectric converting portion; and
a transistor that have a control gate and provided with the floating gate between the control gate and the semiconductor substrate,
wherein a specific resistance of the floating gate and that of the photoelectric converting portion are almost equal to each other.

2. The solid state imaging device according to claim 1,
wherein the floating gate has a peak value of an impurity concentration which is 1×10¹⁸ to 1×10¹⁹/cm³.

3. The solid state imaging device according to claim 1,
wherein the photoelectric converting portion has a peak value of an impurity concentration which is equal to or smaller than 1×10¹⁸/cm³.

4. The solid state imaging device according to claim 1,
wherein an impurity contained in the floating gate is phosphorus or arsenic.

5. The solid state imaging device according to claim 1,
wherein an impurity contained in the floating gate is boron.

6. A method of driving a solid state imaging device including a photoelectric converting portion formed in a semiconductor substrate and serving to generate an electric charge depending on an incident light; a floating gate for storing the electric charge generated in the photoelectric converting portion; and a transistor having a control gate and provided with the floating gate between the control gate and the semiconductor substrate, a specific resistance of the floating gate and that of the photoelectric converting portion being almost equal to each other, the method comprising:
applying an erasing pulse to the control gate to discharge the electric charge stored in the floating gate.

7. The method of driving a solid state imaging device according to claim 6,
wherein the electric charge stored in the floating gate is discharged for a reset period for which the electric charge stored in the photoelectric converting portion is reset.

8. The method of driving a solid state imaging device according to claim 6,
wherein the floating gate has a peak value of an impurity concentration which is 1×10¹⁸ to 1×10¹⁹/cm³.

9. The method of driving a solid state imaging device according to claim 6,
wherein the photoelectric converting portion has a peak value of an impurity concentration which is equal to or smaller than 1×10¹⁸/cm³.

10. The method of driving a solid state imaging device according to claim 6,
wherein an impurity contained in the floating gate is phosphorus or arsenic.

11. The method of driving a solid state imaging device according to claim 6,
wherein an impurity contained in the floating gate is boron.

12. An imaging apparatus comprising the solid state imaging device according to claim 1.
